(19) United States
(12) Patent Application Publication
(10) Pub. No.: US 2026/0369964 A1
(43) Pub. Date: Nov. 19, 2026

(54) SPATIALLY-VARYING GRATINGS FOR OPTICAL EMITTERS

(71) Applicant: Lumentum Operations LLC, San Jose, CA (US)

(72) Inventors: Benjamin KESLER, Livemore, CA (US); Richa DUBEY, Milpitas, CA (US)

(21) Appl. No.: 19/252,065

(22) Filed: Jun. 27, 2025

Related U.S. Application Data
(60) Provisional application No. 63/806,322, filed on May 15, 2025.

(51) Int. Cl. H01S 5/183; G02B 5/18; G03F 7/00

(52) U.S. Cl. CPC H01S 5/18361; G02B 5/1857; G03F 7/70416; H01S 5/18311

(57) ABSTRACT

In some implementations, an optical emitter assembly includes a vertical cavity surface emitting laser (VCSEL) device, wherein the VCSEL device includes a cap layer disposed on an uppermost layer of a distributed Bragg reflector of the VCSEL device, wherein the cap layer includes a surface grating etched thereon, wherein the surface grating includes at least one characteristic that varies with respect to position across the surface grating.

### CROSS-REFERENCE TO RELATED APPLICATION

This Patent Application claims priority to U.S. Provisional Patent Application No. 63/806,322, filed on May 15, 2025, and entitled “SPATIALLY VARYING GRATINGS FOR OPTICAL EMITTER CONTROL.” The disclosure of the prior Application is considered part of and is incorporated by reference into this Patent Application.

### TECHNICAL FIELD

The present disclosure relates generally to optical emitters and to spatially-varying gratings for optical emitters.

### BACKGROUND

Optical emitters, such as vertical cavity surface emitting lasers (VCSELs) may include or be aligned to one or more optical elements, such as a lens, a prism, a filter, or a grating, among other examples. For example, an optical emitter may have a grating disposed on a VCSEL aperture to control light propagation or to assist with mode selection or beam shaping. The grating may include a set of stepped features that can influence an emission direction, polarization, beam divergence, or propagating mode, among other examples, of a beam being emitted from an optical emitter, such as a VCSEL. Different types of gratings may include surface relief gratings, sub-wavelength gratings, or diffractive gratings, among other examples.

### SUMMARY

In some implementations, an optical emitter assembly includes a vertical cavity surface emitting laser (VCSEL) device, wherein the VCSEL device includes a cap layer disposed on an uppermost layer of a distributed Bragg reflector (DBR) of the VCSEL device, wherein the cap layer includes a surface grating etched thereon, wherein the surface grating includes at least one characteristic that varies with respect to position across the surface grating.

In some implementations, a method includes providing, by a device, a substrate associated with a VCSEL device; coating, by the device, the substrate with a material layer; performing, by the device, a grayscale lithography operation using a grayscale mask to form a pattern in the material layer, wherein the pattern varies with respect to position along the material layer; and transferring, by the device, the pattern in the material layer into a surface of the VCSEL device to form a surface grating on the VCSEL device, wherein the surface grating includes at least one characteristic that varies with respect to position across the surface grating in connection with the pattern of the grayscale mask varying with respect to position along the material layer.

In some implementations, a VCSEL device includes a first DBR; a gain region disposed on the first DBR, the gain region being associated with an oxide aperture with a particular oxide aperture diameter; a second DBR disposed on the gain region; a cap layer disposed on an uppermost layer of a DBR of the VCSEL device, wherein the cap layer includes a surface grating etched thereon, wherein a first diameter of a first characteristic of surface grating is less than the oxide aperture diameter of the VCSEL device, wherein a second diameter of a second characteristic of the surface grating is greater than the oxide aperture diameter of the VCSEL device.

### BRIEF DESCRIPTION OF THE DRAWINGS

FIGS. 1A and 1B are diagrams depicting views of an example optical emitter.

FIGS. 2A-2D is a diagram of an example implementation associated with a spatially-varying grating for an optical emitter.

FIGS. 3A-3B are diagrams of an examples of optical performance associated with spatially-varying gratings for optical emitters.

FIG. 4 is a flowchart of an example process associated with using a grayscale lithography process to form a spatially-varying grating.

### DETAILED DESCRIPTION

The following detailed description of example implementations refers to the accompanying drawings. The same reference numbers in different drawings may identify the same or similar elements.

An optical emitter, such as a vertical cavity surface emitting laser (VCSEL) device, may include one or more features to control a polarization and/or a mode of light being emitted. One technique for mode control of a VCSEL device is to create a surface relief etch on a layer of the VCSEL device. In this case, a bulk etch is performed on an uppermost layer of a VCSEL emission-side mirror, which spatially modifies a reflectance of the mirror and introduces a spatially-varying change in a threshold gain. The spatially-varying change in the threshold gain impacts all VCSEL optical modes, but most heavily impacts modes that have a spatial overlap between a mode profile and a region with particularly low reflectance or particularly high reflectance. From a manufacturing standpoint, a VCSEL device with a surface relief etch may be configured to have the VCSEL top mirror be a low reflectance mirror (without the subsequent bulk etch operation) and a bulk etch operation is performed in a region of the VCSEL device where lasing is desired. This occurs because the etch depth to achieve high reflectance (from an initial low reflectance configuration) has a wider tolerance range than occurs when attempting to etch down from an initial high reflectance configuration to a subsequent low reflectance configuration. The bulk etch operation is performed at a center of an oxide aperture, such that a diameter of an etched surface relief is smaller than a diameter of the oxide aperture, thereby maximizing an overlap between a fundamental VCSEL mode and a minimizing an overlap with other higher order modes and thereby achieving single-fundamental-mode output for the VCSEL with a Gaussian-type beam profile.

For polarization control, an etched surface grating can be formed in the same uppermost layer of the VCSEL top mirror as is used for mode control. When only controlling polarization (and not mode), a region that is etched for the surface grating can be configured to be larger than an oxide aperture diameter to maximize an overlap with all possible supported modes of the VCSEL. In this case, the VCSEL top mirror is configured to maximize reflectance, such that the surface grating can eliminate one of the two polarization directions from a VCSEL output without impacting overall performance.

However, when both polarization control and mode control are desired, then the etched surface grating is used for both the mode control and for the polarization control, which results in a balancing between having the surface grating being smaller than the oxide aperture (as is used for mode control) and having the surface grating be larger than the oxide aperture (as is used for polarization control). In this case, the surface grating is disposed on a low-reflectance VCSEL top mirror and a surface grating region experiences increased reflectance, but for only a single polarization direction. By disposing the surface grating at a center of oxide aperture, the VCSEL device can be configured to emit a single-fundamental-mode single-polarization beam. However, balancing different features of the surface grating to achieve polarization control and mode control may result in less than ideal performance with respect to both polarization control and mode control. In other words, the VCSEL device may emit a beam that may be only partially polarized and may have some higher-order modes in addition to a fundamental mode.

Some implementations described herein enable polarization and mode control in an optical emitter, such as a VCSEL device. For example, some implementations may use a grayscale lithography process to form a spatially-varying surface grating for a VCSEL device, thereby achieving both polarization control (e.g., single polarization emission) and mode control (e.g., single fundamental mode emission). As a result, the spatially-varying surface grating enables more granular control of optical emitters, thereby allowing for higher-power, higher polarization single-mode VCSELs for applications, such as self-mixing interferometry, and for higher-power, higher polarization multi-mode VCSELs for improved LIDAR performance. Additionally, or alternatively, by using a grayscale lithography operation, the spatially-varying surface grating can be formed using a single masking and photolithography step, thereby improving an accuracy of the formation of a spatially-varying surface grating relative to other techniques and improving an optical performance of an optical emitter assembly that includes a spatially-varying surface grating. In some implementations, a cap layer of a VCSEL device may have a partially out-of-phase cap layer thickness with a surface grating that reduces reflectance. In other words, a grating depth can restore, locally, a same reflectively as an in-phase cap layer for, for example, a partially out-of-phase cap layer. In some implementations, the partially out-of-phase cap layer results in a region where a grating (e.g., with a period on an order of a lasing wavelength) can increase reflectance and can reach a similar reflectance level to an in-phase cap thickness.

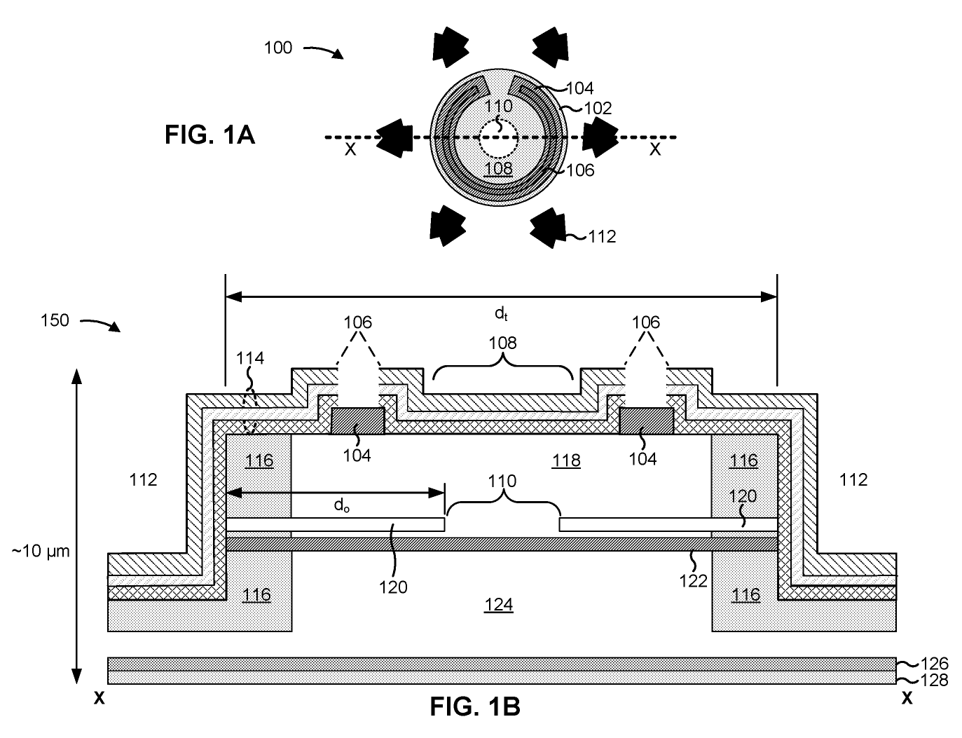

FIGS. 1A and 1B are diagrams depicting a top view of an example emitter 100 and a cross-sectional view 150 of example emitter 100 along the line X-X, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 may include an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100.

As shown in FIG. 1A, emitter 100 includes an ohmic metal layer 104 (e.g., a P-Ohmic metal layer or an N-Ohmic metal layer) that is constructed in a partial ring-shape (e.g., with an inner radius and an outer radius). An area of ohmic metal layer 104 is covered by a protective layer (e.g. a dielectric layer or a passivation layer) of emitter 100 and another area of ohmic metal layer 104 is exposed by via 106, described below. As shown, ohmic metal layer 104 overlaps with implant protection layer 102. Such a configuration may be used, for example, in the case of a P-up/top-emitting emitter 100. In the case of a bottom-emitting emitter 100, the configuration may be adjusted as needed.

Not shown in FIG. 1A, emitter 100 includes a protective layer in which via 106 is formed (e.g., etched). An area of ohmic metal layer 104 is exposed by via 106 (e.g., the shape of the area may be a result of the shape of via 106) while another area of ohmic metal layer 104 is covered by some protective layer. The protective layer may cover all of the emitter other than the vias. As shown, via 106 is formed in a partial ring-shape (e.g., similar to ohmic metal layer 104) and is formed over ohmic metal layer 104 such that metallization on the protection layer contacts ohmic metal layer 104. In some implementations, via 106 and/or ohmic metal layer 104 may be formed in another shape, such as a full ring-shape or a split ring-shape.

As further shown, emitter 100 includes an optical aperture 108 in a portion of emitter 100 within the inner radius of the partial ring-shape of ohmic metal layer 104. Emitter 100 emits a laser beam via optical aperture 108. As further shown, emitter 100 also includes a current confinement aperture 110 (e.g., an oxide aperture formed by an oxidation layer of emitter 100 (not shown)). Current confinement aperture 110 is formed below optical aperture 108.

As further shown in FIG. 1A, emitter 100 includes a set of trenches 112 (e.g., oxidation trenches) that are spaced (e.g., equally, unequally) around a circumference of implant protection layer 102. How closely trenches 112 can be positioned relative to the optical aperture 108 is dependent on the application, and is typically limited by implant protection layer 102, ohmic metal layer 104, via 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a set of six trenches 112, in practice, other configurations are possible, such as a compact emitter that includes five trenches 112, seven trenches 112, or another quantity of trenches. In some implementations, trench 112 may encircle emitter 100 to form a mesa structure dt. As another example, while emitter 100 is a circular emitter design, in practice, other designs may be used, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a VCSEL, other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, and/or emission profile. In other words, emitter 100 is not particular to an emitter with a given performance characteristic.

As shown in FIG. 1B, the example cross-sectional view may represent a cross-section of emitter 100 that passes through, or between, a pair of trenches 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a protective layer 114 (e.g. a dielectric passivation/mirror layer), and an ohmic metal layer 104. As shown, emitter 100 may have, for example, a total height that is approximately 10 µm.

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or another type of semiconductor layer.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al2O3 layer formed as a result of oxidation of an AlAs or AlGaAs layer. Trenches 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 4 μm to approximately 20 μm. In some implementations, a size of current confinement aperture 110 may depend on a distance between trenches 112 that surround emitter 100. For example, trenches 112 may be etched to expose the epitaxial layer from which oxidation layer 120 is formed. Here, before protective layer 114 is formed (e.g., deposited), oxidation of the epitaxial layer may occur for a particular distance (e.g., identified as do in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as a hydrogen/proton implanted material or a similar implanted element to reduce conductivity. In some implementations, implant isolation material 116 may define implant protection layer 102.

Protective layer 114 may include a layer that acts as a protective passivation layer and which may act as an additional DBR. For example, protective layer 114 may include one or more sub-layers (e.g., a dielectric passivation layer and/or a mirror layer, a SiO2 layer, a Si3N4 layer, an Al2O3 layer, or other layers) deposited (e.g., by chemical vapor deposition, atomic layer deposition, or other techniques) on one or more other layers of emitter 100.

As shown, protective layer 114 may include one or more vias 106 that provide electrical access to ohmic metal layer 104. For example, via 106 may be formed as an etched portion of protective layer 114 or a lifted-off section of protective layer 114. Optical aperture 108 may include a portion of protective layer 114 over current confinement aperture 110 through which light may be emitted.

Ohmic metal layer 104 may include a layer that makes electrical contact through which electrical current may flow. For example, ohmic metal layer 104 may include a Ti and Au layer, a Ti and Pt layer and/or an Au layer, or the like, through which electrical current may flow (e.g., through a bondpad (not shown) that contacts ohmic metal layer 104 through via 106). Ohmic metal layer 104 may be P-ohmic, N-ohmic, or other forms known in the art. Selection of a particular type of ohmic metal layer 104 may depend on the architecture of the emitters and is well within the knowledge of a person skilled in the art. Ohmic metal layer 104 may provide ohmic contact between a metal and a semiconductor and/or may provide a non-rectifying electrical junction and/or may provide a low-resistance contact. In some implementations, emitter 100 may be manufactured using a series of steps. For example, bottom mirror 124, active region 122, oxidation layer 120, and top mirror 118 may be epitaxially grown on substrate layer 126, after which ohmic metal layer 104 may be deposited on top mirror 118. Next, trenches 112 may be etched to expose oxidation layer 120 for oxidation. Implant isolation material 116 may be created via ion implantation, after which protective layer 114 may be deposited. Via 106 may be etched in protective layer 114 (e.g., to expose ohmic metal layer 104 for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set of layers (e.g., one or more layers) of emitter 100 may perform one or more functions described as being performed by another set of layers of emitter 100 and any layer may comprise more than one layer.

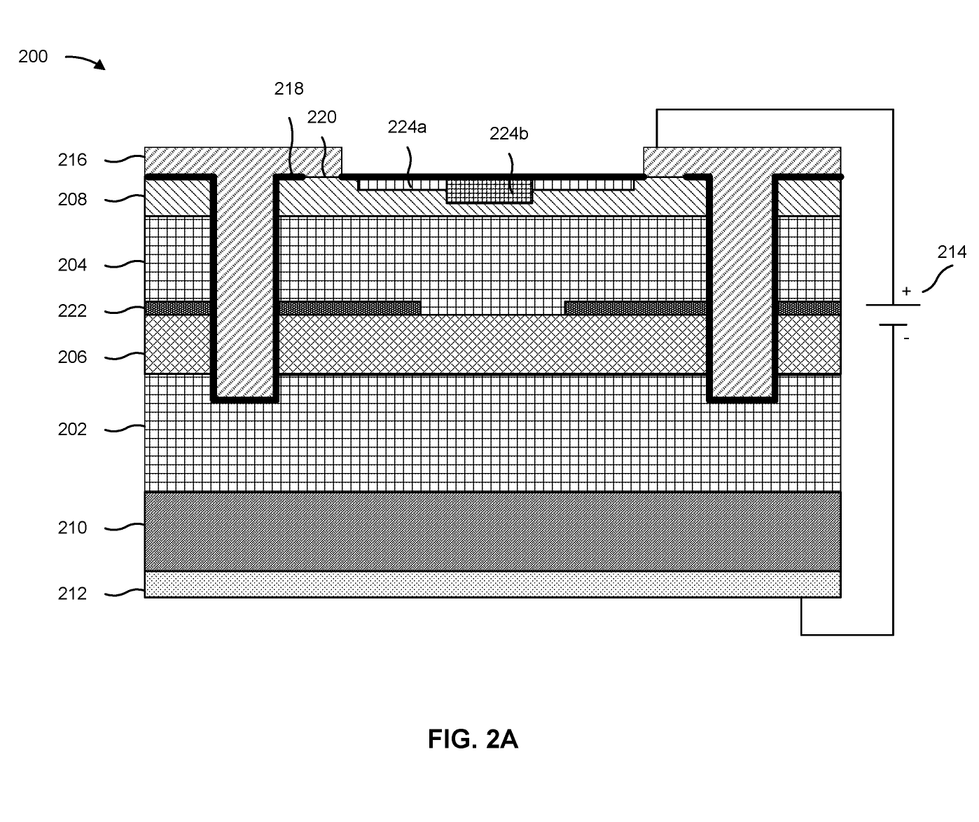

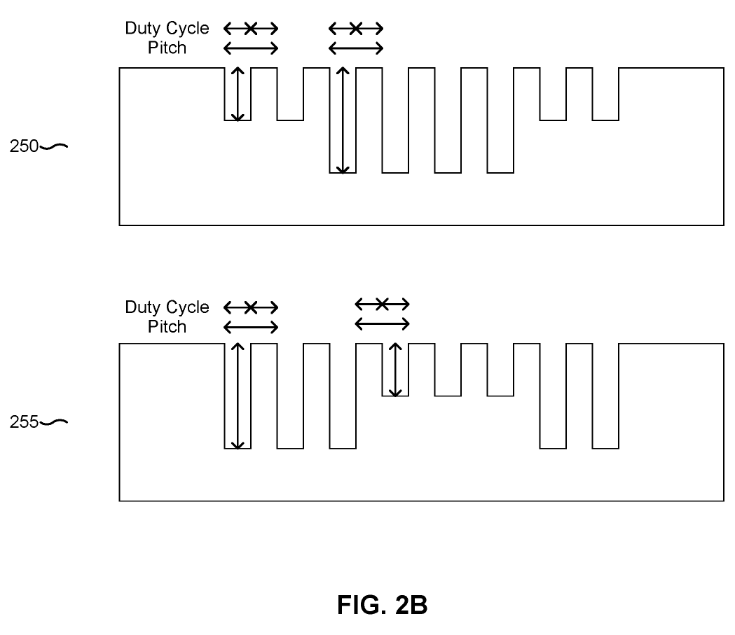

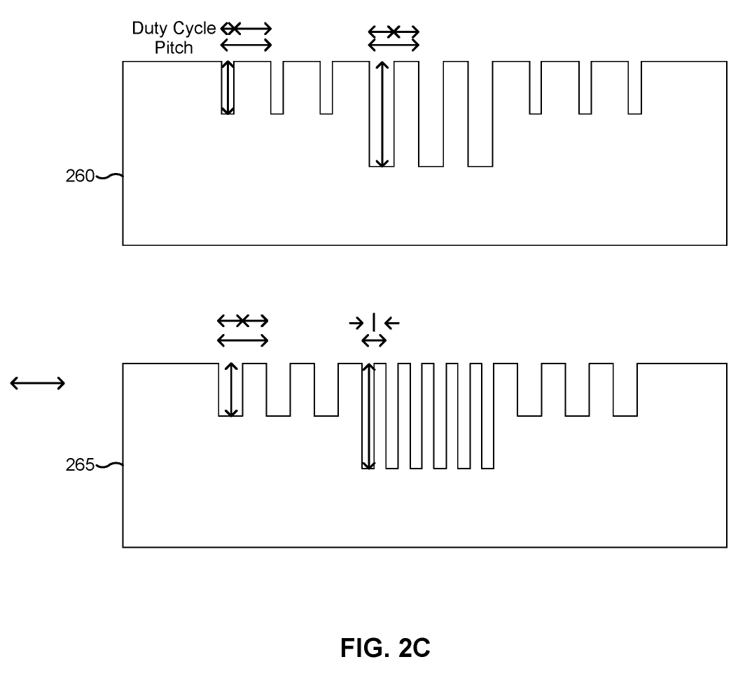

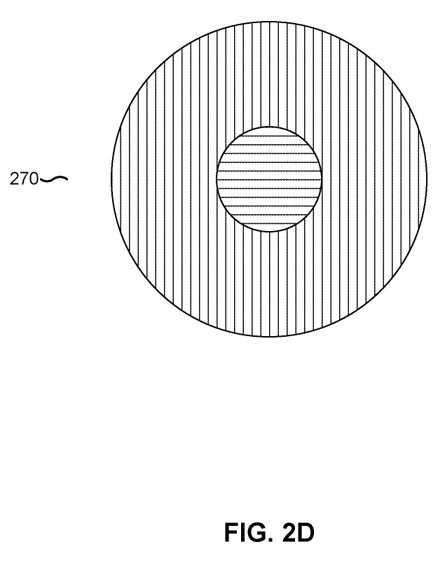

FIGS. 2A-2D are diagrams of an example implementation associated with a spatially-varying grating for an optical emitter. As shown in FIG. 2A, an optical emitter assembly 200, which may include a VCSEL device, includes a bottom DBR 202 and a top DBR 204 that sandwich a gain region 206. A cap layer 208 may be disposed on top of the top DBR 204. The bottom DBR 202, the top DBR 204, the gain region 206, and the cap layer 208 may be disposed on top of a substrate 210. A cathode contact 212 may be disposed on a bottom of the substrate 210 and may be electrically connected, via a driving voltage source 214, to an anode contact 216, which is disposed on top of the cap layer 208 and extends down through a portion of the optical emitter assembly 200 toward the bottom DBR 202, as shown. The anode contact 216 may be electrically isolated from one or more other portions of the optical emitter assembly 200 (e.g., the cap layer 208, the top DBR 204, the gain region 206, or the bottom DBR 202) by an electrical isolation layer 218, except at an electrical isolation remove area 220, where the anode contact 216 is in electrical contact with the cap layer 208. Although some implementations are depicted with a cathode on a bottom and an anode on a top of a VCSEL device, it is contemplated that positions may differ, such as having a cathode on a top and an anode on a bottom of a VCSEL device.

The gain region 206 may include an oxidation aperture 222, which is associated with an oxidation aperture diameter for emission of an optical beam through a top of the optical emitter assembly 200. The cap layer 208 may include a surface grating 224, which includes a shallow etched surface grating area 224a and a deep etched surface grating area 224b. Although each etched surface grating area 224a/b has different levels therein, the etched surface grating areas 224a/b, as shown, differ with respect to a depth with which the different levels are etched. In other words, the shallow etched surface grating area 224a may include pillars and valleys with a first difference between a height of the pillars and a depth of the valleys and the deep etched surface grating area 224b may include pillars and valleys with a second difference between a height of the pillars and a depth of the valleys (e.g., the second difference is a larger difference than the first difference).

In some implementations, the surface grating 224 is a spatially-varying grating (e.g., at least one characteristic varies with respect to position) formed using a grayscale lithography process, which may also be referred to as a “gray scale” or “gray-scale” lithography process. For example, as described in more details herein, a grayscale lithography process can be used on the cap layer 208 to etch a discrete spatially-varying grating in a single masking and etching step. Additionally, or alternatively, the grayscale lithography process can be applied to etch a continuously-varying spatially-varying grating. Additionally, or alternatively, the surface grating 224 may be formed by multiple masking and/or etching steps.

The shallow etched surface grating area 224a may be associated with a second diameter, and the deep etched surface grating area 224b may be associated with a third diameter. For example, the shallow etched surface grating area 224a may have a larger diameter than the oxidation aperture 222, and the deep etched surface grating area 224a may have a smaller diameter than the oxidation aperture 222. In some implementations, a position of the etched surface grating areas 224a/b may be different than is depicted. For example, rather than a deep etched surface grating area 224b having the third diameter and being at a center of the oxidation aperture 222 and a shallow etched surface grating area 224a having the second diameter and being at edges of the oxidation aperture 222, the deep etched surface grating area 224b may have the second diameter and be at edges of the oxidation aperture 222, and the shallow etched surface grating area 224a may have the third diameter and may be at a center of the oxidation aperture 222.

Additionally, or alternatively, although some implementations are described herein in terms of the surface grating 224 having a spatially-varying characteristic of etch depth (e.g., a shallow etched surface grating area 224a and a deep etched surface grating area 224b), it is contemplated that other characteristic differences are possible. For example, the surface grating 224 may include additional regions with a third, fourth, or nth etch depth. Additionally, or alternatively, the surface grating 224 may include a continuously varying etch depth (e.g., as a function of position). Additionally, or alternatively, the surface grating 224 may include different grating duty cycles, grating pitches, grating physical directions, or grating orientations, among other examples.

In one example, rather than (or in addition to) having different depths, the surface grating 224 may have different grating pitches in a first area (e.g., a first grating pitch area) with a first diameter and a second area (e.g., a second grating pitch area) with a second diameter. Additionally, or alternatively, the surface grating 224 may have different grating duty cycles in a first area (e.g., a first grating duty cycle area) with a first diameter and a second area (e.g., a second grating duty cycle area) with a second diameter. Additionally, or alternatively, rather than two or more discrete areas of differing characteristics (e.g., etch depth, pitch, or duty cycle), the surface grating 224 may have continuously varying characteristics across different spatial positions.

For example, as shown in FIG. 2B, and by reference number 250, a surface grating may include a first, shallow depth in an outer area of the grating and a second, deep depth in an inner area of the grating, but may include the same pitch and duty cycle in both the outer area and the inner area. It is understood that shallow and deep are relative terms, such that the shallow depth is shallower than the deep depth and the deep depth is deeper than the shallow depth. Additionally, it is understood that a pattern, such as a magnitude of the shallow depth and the deep depth, as provided in a surface grating of a VCSEL may be the same or different from the magnitude of the shallow depth or the deep depth in a material layer that is used to transfer the pattern into the surface grating (e.g., from a grayscale mask). Additionally, it is understood that although the etches are depicted as rectangular etches with vertical walls, other shapes or forms may be used for the etches, such as curved or angular walls.

As shown in FIG. 2B, and by reference number 255, a surface grating may include a first, deep etch in an outer area of the grating and a second, shallow etch in an inner area of the grating, but may include the same pitch and duty cycle in both the outer area and the inner area. In another example, as shown in FIG. 2C, and by reference number 265, a surface grating may include a first, shallow etch and a first duty cycle in an outer area of the grating and a second, deep etch and a second duty cycle in an inner area of the grating, but may include the same pitch in both the outer area and the inner area. Similarly, as shown in FIG. 2C, and by reference number 265, a surface grating may include a first, shallow etch and a first pitch in an outer area of the grating and a second, deep etch and a second pitch in an inner area of the grating, but may include the duty cycle in both the outer area and the inner area. In another example, as shown in FIG. 2D, and by reference number 270 in a top-down view, a surface grating may include a first orientation (e.g., shown as vertical in the top-down view) in an outer area of the grating and a second orientation (e.g., shown as horizontal in the top-down view) in the inner area of the grating.

In some implementations, the surface grating 224 etched (e.g., using physical or chemical etching, among other examples) into the cap layer 208 of the optical emitter assembly 200 (e.g., a VCSEL) may have a grating pitch (e.g., a period) in a range of 0.2 to 1.5 times the effective lasing wavelength (λ) of the VCSEL in the cap layer material, for example, from 50 nanometers (nm) to 500 nm for a near-infrared emitting VCSEL. Additionally, or alternatively, the grating pitch may be in a range of 0.5 to 1.5 times the effective lasing wavelength, which is in a range of 150 nm to 300 nm. As one particular example, the grating pitch may be in a range of 250 nm to 400 nm. The grating duty cycle, which may be a ratio of a width of a grating ridge to a period of the grating may be in a range of 30% to 70%. In one particular example, the grating pitch may be approximately 50%. The etch depth of the grating features may range from 20 nm to 300 nm, in some implementations. Additionally, or alternatively, the etch depth may range from 50 nm to 300 nm. As one particular example, central region etch depth (e.g., the deep etched surface grating area 224b) may be approximately 275 nm and peripheral region etch depth (e.g., the shallow etched surface grating area 224a) may be approximately 150 nm. For a continuously varying grating, the etch depth may be a monotonic or non-monotonic function of position, varying smoothly between values. The cap layer thickness of the cap layer 208 may be selected to be between 0.2λ and 2.5λ effective optical thickness, which may correspond to a range of 50 nm to 1250 nm and may be related to a refractive index of the cap layer material and a desired reflectance phase condition. In one particular example, the cap layer thickness may be in a range of approximately 390 nm to 450 nm.

In some implementations, the shallow etched surface grating area 224a, as shown, can control a polarization of a beam being emitted from the optical emitter assembly 200. For example, by the shallow etched surface grating area 224a having a larger diameter than an oxidation aperture diameter of the oxidation aperture 222, polarization control can be achieved without influencing spatial mode dynamics of the beam. Additionally, or alternatively, the deep etched surface grating area 224b, by having a smaller diameter than the oxidation aperture diameter of the oxidation aperture 222, can help control a polarization of light being emitted from the optical emitter assembly 200 and influence spatial mode dynamics of the light. The thickness of the deep etched surface grating area 224b may be configured, such that the mirror stack (e.g., the top DBR 204 and the bottom DBR 202) is low reflectance in regions without the deep etched surface grating area 224b to prevent lasing transverse modes, which have a large overlap with such regions. By including the shallow etched surface grating area 224a, a reflectance of the mirror stack is further reduced and polarization control (e.g., polarization selectively) is further improved relative to having only the deep etched surface grating area 224b. And, similarly, by including the presence of the deep etched surface grating area 224b, a spatial mode dynamics selectivity is improved relative to having only the shallow etched surface grating area 224a. In some implementations, a partially out-of-phase cap layer, formed by the surface grating areas 224a and 224b results in a region where a grating (e.g., with a period on an order of a lasing wavelength) can increase reflectance and can reach a similar reflectance level to an in-phase cap thickness.

By further reducing the reflectance, the surface grating 224 improves a flexibility of cap thickness of the cap layer 208, thereby improving manufacturability as well as improving lasing performance of the optical emitter assembly 200 relative to other VCSELs. Additionally, or alternatively, the cap thickness of the cap layer 208 can be configured to be partially out-of-phase and a grating pitch of the surface grating 224 can be configured to be near-wavelength (rather than sub-wavelength), which may further improve manufacturability, such as by enabling mass production fabrication techniques to be used for manufacturing the optical emitter assembly 200. In some implementations, the surface grating 224 can be a sub-wavelength grating, a near-wavelength grating, or a larger-than-wavelength grating.

By providing multiple grating etch depths (or other characteristic differences, as described above), if the optical emitter assembly 200 has large oxide aperture diameter and is driven to a high enough current to cause higher-order modes to lase, the high-order modes will lase in the same polarization direction as the central region, which avoids a negative impact to any polarization sensitive optics that may be used in connection with the optical emitter assembly 200 and avoids negative performance impacts to an optical system that includes the optical emitter assembly 200.

As indicated above, FIGS. 2A-2D are provided as examples. Other examples may differ from what is described with regard to FIGS. 2A-2D.

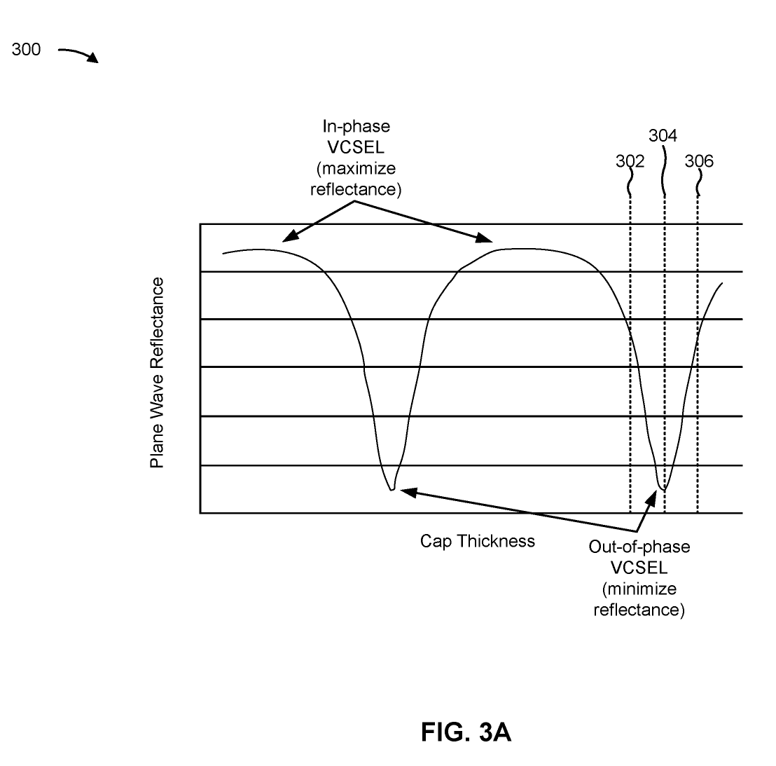

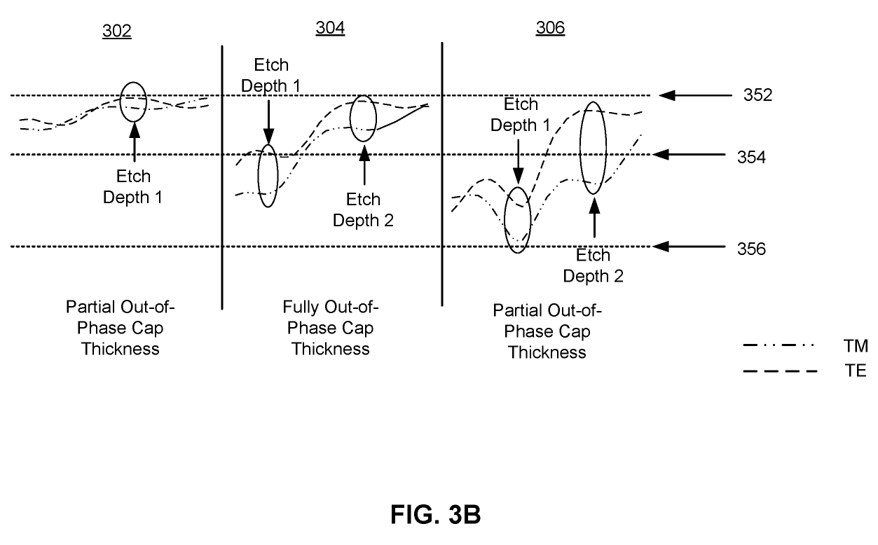

FIGS. 3A-3B are diagrams of an examples of optical performance associated with spatially-varying gratings for optical emitters. As shown in FIGS. 3A, example 300 illustrates a reflectance of a VCSEL output mirror as a function of cap thickness. In a mode-control scenario, a reflectance of the VCSEL output mirror is to be minimized in regions where lasing is not desired. This can be achieved by spatial bulk etch of the cap layer, which does not introduce polarization control. In such a scenario, when using a surface relief technique, the cap thickness is configured to be in-phase with high reflectance in regions where lasing is desired and is etched to be out-of-phase with low reflectance in regions where no lasing is desired. In contrast, when using an inverted surface relief technique, the cap thickness is configured to be out-of-phase with low-reflectance in regions where no lasing is desired and is etched to be in-phase with high reflectance in regions where lasing is desired. However, by incorporating a surface grating, as described herein, the spatially-varying grating etch has different behaviors across different operating conditions. For example, at a first depth 302, there is a relatively high level of reflectance, which can be referred to as being “partially-out-of-phase”; at a second depth 304, there is a relatively low level of reflectance, which is referred to as being “out-of-phase”; and at a third depth 306, there is a relatively high level of reflectance again, which can be referred to as being “partially-out-of-phase”.

As shown in FIG. 3B, example 350 illustrates transverse electric (TE) polarization and transverse magnetic (TM) polarization reflectance at different cap thicknesses and grating etch depths (with a common grating pitch and duty cycle). Here, reference lines 352, 354, and 356 indicate the plane wave reflectance with no grating for in-phase, partially out-of-phase, and fully out-of-phase cap thicknesses, respectively. As shown, for the first cap thickness associated with the first depth 302, an unetched reflectance is lower than is achieved by a grating etch depth, which indicates that multi-region grating etch may be less effective for such a configuration. In contrast, for the second depth 304, a multi-region grating etch may be effective for VCSEL devices that are to operate at two different driving currents, such as a lower current for single-mode, single-polarization operation (e.g., using a grating in the center with the second etch depth) and a higher current for more total power where single-mode operation is not needed, but single-polarization operation is desired (e.g., resulting in emission of higher-order modes while maintaining polarization selectively using an outer grating with the first etch depth). Similarly, for the third depth 306, a multi-region grating etch may be effective for VCSEL devices that are to operate with strong single-mode, single-polarization performance. For example, the central grating with the second etch depth introduces a large difference between TE and TM reflectance across all three cap thicknesses, even more than occurs at reference line 354. As a result, the central grating with the second etch depth can achieve a largest polarization selectively, while maintaining high enough reflectivity for a desired polarization to ensure good laser performance. Etching a grating in an outer region with the first etch depth reduces both the TE reflectance and the TM reflectance below what occurs for a partially etched region, as shown by reference line 354, thereby maintaining single-mode operation and providing polarization selectively, which is an improvement over the use of a bulk etch, by ensuring that polarization sensitive optics are not impacted in an event of operating a VCSEL device beyond a single-mode regime. Although some implementations are described herein in terms of a particular set of use cases, many other use cases, in which different levels of polarization selectively or mode control are desired, are contemplated.

As indicated above, FIGS. 3A-3B are provided as an example. Other examples may differ from what is described with regard to FIGS. 3A-3B.

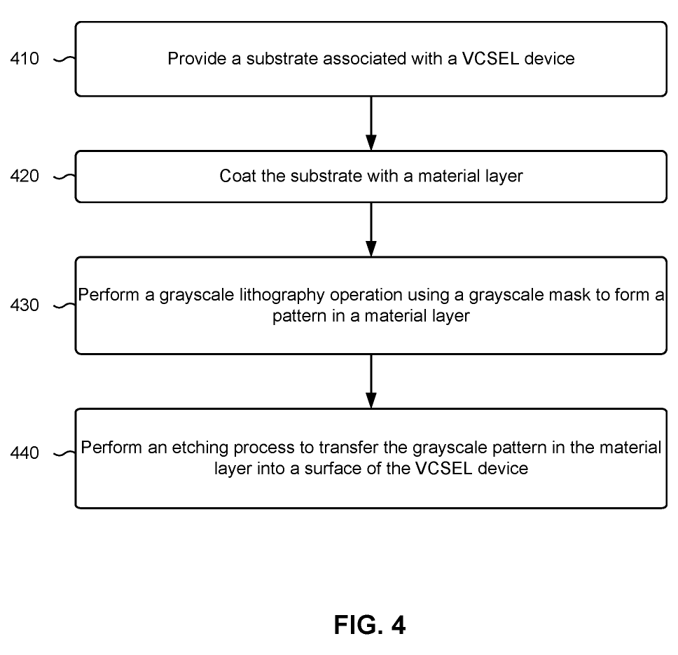

FIG. 4 is a flowchart of an example process 400 associated with using a grayscale lithography process to form a spatially-varying grating. One or more process blocks of FIG. 4 are performed by a manufacturing device (e.g., a deposition device, a masking device, or a photolithography device) and/or by another device or a group of devices separate from or including the manufacturing device.

As shown in FIG. 4, process 400 includes providing a substrate associated with a VCSEL device (block 410). For example, the manufacturing device may provide a substrate associated with a VCSEL device, as described above.

As further shown in FIG. 4, process 400 includes coating the substrate with a material layer (block 420). For example, the manufacturing device may coat the substrate with a material layer, as described above.

As further shown in FIG. 4, process 400 includes performing a grayscale lithography operation using a grayscale mask to form a pattern in a material layer (block 430). For example, the manufacturing device may perform a grayscale lithography operation using a grayscale mask to form a pattern in a material layer, wherein the pattern varies with respect to position along the material layer, as described above. The grayscale mask may be exposed to light to transfer a pattern from the grayscale mask into the material layer.

As further shown in FIG. 4, process 400 includes performing an etching process to transfer the grayscale pattern in the material layer into a surface of the VCSEL device (block 440). For example, the manufacturing device may perform an etching process to transfer the grayscale pattern in the material layer into a surface of the VCSEL device, wherein the surface of the VCSEL device includes at least one characteristic that varies with respect to position across the surface in connection with the pattern varying with respect to position along the material layer, as described above. The material layer may be exposed to chemical or physical etching to transfer the pattern from the material layer to a surface grating.

In some implementations, the photolithography operation is performed to form the surface grating with different characteristics (e.g., two etch depths) in a single fabrication step. For example, rather than performing two etch steps, which can result in poor alignment between respective grating regions and poor performance, the use of a grayscale mask, with photolithography, enables forming a multi-region surface grating in a single etch step. In this way, each region, of the multiple regions, remains aligned to each other as a result of the single etch step, thereby improving performance. Additionally, or alternatively, use of a grayscale mask enables formation of a continuously varying surface grating, as described above. For example, when etch depth of a spatially-varying grating varies continuously, rather than as discrete regions, the use of a grayscale mask enables formation of such a continuous varying grating.

Process 400 may include additional aspects, such as any single aspect or any combination of aspects described herein and/or in connection with one or more other processes described elsewhere herein.

In a first aspect, performing the grayscale lithography operation includes exposing the grayscale mask to a configured wavelength of light to form the pattern in the material layer.

In a second aspect, alone or in combination with the first aspect, the pattern in the material layer varies with respect to at least one parameter with respect to position along the material layer.

In a third aspect, alone or in combination with one or more of the first and second aspects, the at least one parameter includes at least one of an optical density, a pattern, a fill factor, a set of halftone dots, a three-dimensional topography, a surface level, a layer pattern, a polarization, a diffraction effect, or an orientation.

In a fourth aspect, alone or in combination with one or more of the first through third aspects, wherein transferring the pattern into the surface of the VCSEL device comprises: transferring a first part of the pattern; and transferring a second part of the pattern concurrent with transferring the first part of the pattern, wherein the first part is smaller than an oxide aperture of the VCSEL device, and wherein the second part is larger than the oxide aperture.

In a fifth aspect, alone or in combination with one or more of the first through fourth aspects, wherein the surface of the VCSEL device, in which the surface grating is formed, includes a cap layer of the VCSEL device.

In a sixth aspect, alone or in combination with one or more of the first through fifth aspects, the VCSEL device includes a bottom distributed Bragg reflector (DBR), a gain region disposed on the bottom DBR, and a top DBR disposed on the gain region, and wherein the material layer is disposed on the top DBR.

Although FIG. 4 shows example blocks of process 400, in some implementations, process 400 includes additional blocks, fewer blocks, different blocks, or differently arranged blocks than those depicted in FIG. 4. Additionally, or alternatively, two or more of the blocks of process 400 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

When a component or one or more components (e.g., a manufacturing device or one or more manufacturing devices) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature’s relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical emitter assembly, comprising:
a vertical cavity surface emitting laser (VCSEL) device,
wherein the VCSEL device includes a cap layer disposed on an uppermost layer of a distributed Bragg reflector of the VCSEL device,
wherein the cap layer includes a surface grating etched thereon,
wherein the surface grating includes at least one characteristic that varies with respect to position across the surface grating.

2. The optical emitter assembly of claim 1, wherein the at least one characteristic includes an etch depth.

3. The optical emitter assembly of claim 1, wherein the at least one characteristic includes a grating duty cycle.

4. The optical emitter assembly of claim 1, wherein the at least one characteristic includes a grating pitch.

5. The optical emitter assembly of claim 1, wherein the at least one characteristic includes a grating direction or orientation.

6. The optical emitter assembly of claim 1, wherein the cap layer has a thickness that is partially out-of-phase with a lasing wavelength of the VCSEL device.

7. The optical emitter assembly of claim 1, wherein a diameter of the surface grating is less than an oxidation aperture diameter of an oxide aperture of the VCSEL device.

8. The optical emitter assembly of claim 7, wherein the diameter is a first diameter of the surface grating corresponding to a first etch depth of the surface grating, and wherein a second etch depth of the surface grating is associated with a second diameter that is larger than the first diameter.

9. The optical emitter assembly of claim 1, wherein the surface grating is formed using a grayscale mask and photolithography operation.

10. The optical emitter assembly of claim 9, wherein the grayscale mask and photolithography operation forms a first etch depth at a first position on the surface grating concurrent with forming a second etch depth at a second position on the surface grating.

11. A method, comprising:
providing, by a device, a substrate associated with a vertical cavity surface emitting laser (VCSEL) device;
coating, by the device, the substrate with a material layer;
performing, by the device, a grayscale lithography operation using a grayscale mask to form a pattern in the material layer, wherein the pattern varies with respect to position along the material layer; and
transferring, by the device, the pattern in the material layer into a surface of the VCSEL device to form a surface grating on the VCSEL device, wherein the surface grating includes at least one characteristic that varies with respect to position across the surface grating in connection with the pattern of the grayscale mask varying with respect to position along the material layer.

12. The method of claim 11, wherein performing the grayscale lithography operation comprises:
exposing the grayscale mask to a configured wavelength of light to form the pattern in the material layer.

13. The method of claim 11, wherein the pattern of the grayscale mask varies with respect to at least one parameter with respect to position along the material layer.

14. The method of claim 13, wherein the at least one parameter includes at least one of:
an optical density,
a pattern,
a fill factor,
a set of halftone dots,
a three-dimensional topography,
a surface level,
a layer pattern,
an orientation
a polarization, or
a diffraction effect.

15. The method of claim 11, transferring the pattern into the surface of the VCSEL device comprises:
transferring a first part of the pattern; and
transferring a second part of the pattern concurrent with transferring the first part of the pattern, wherein the first part is smaller than an oxide aperture of the VCSEL device, and wherein the second part is larger than the oxide aperture.

16. The method of claim 11, wherein the surface of the VCSEL device, in which the surface grating is formed, includes a cap layer of the VCSEL device.

17. A vertical cavity surface emitting laser (VCSEL) device, comprising:
a first distributed Bragg reflector (DBR);
a gain region disposed on the first DBR,
the gain region being associated with an oxide aperture with a particular oxide aperture diameter;
a second DBR disposed on the gain region; and
a cap layer disposed on an uppermost layer of a distributed Bragg reflector of the VCSEL device,
wherein the cap layer includes a surface grating etched thereon,
wherein a first diameter of a first characteristic of surface grating is less than the oxide aperture diameter of the VCSEL device,
wherein a second diameter of a second characteristic of the surface grating is greater than the oxide aperture diameter of the VCSEL device.

18. The VCSEL device of claim 17, wherein the surface grating includes at least one characteristic that varies with respect to position across the surface grating.

19. The VCSEL device of claim 17, wherein the at least one characteristic includes at least one of:
an etch depth,
a grating duty cycle,
a grating pitch,
a grating direction, or
a grating orientation.

20. The VCSEL device of claim 17, wherein the surface grating is formed using a grayscale mask and photolithography operation.
